(19) United States
(12) Patent Application Publication
(10) Pub. No.: US 2024/0106188 A1
(43) Pub. Date: Mar. 28, 2024

(54) MANUFACTURING METHOD OF CAP AND LIGHT SOURCE DEVICE, CAP, AND LIGHT SOURCE DEVICE

(71) Applicant: NICHIA CORPORATION, Anan-shi (JP)

(72) Inventor: Tadaaki MIYATA, Yokohama-shi (JP)

(73) Assignee: NICHIA CORPORATION, Anan-shi (JP)

(21) Appl. No.: 18/449,784

(22) Filed: Aug. 15, 2023

(30) Foreign Application Priority Data
Sep. 28, 2022 (JP) 2022-154536

(51) Int. Cl. H01S 5/02257; B32B 17/06; H01S 5/02218

(52) U.S. Cl. CPC H01S 5/02257; B32B 17/061; H01S 5/02218; B32B 2307/40; B32B 2310/021; B32B 2311/00; B32B 2315/08; B32B 2457/00

(57) ABSTRACT

A cap has a cavity for accommodating a light-emitting element and includes a front wall defining a front surface of the cavity and made of a material that transmits light emitted from the light-emitting element; a rear wall defining a rear surface of the cavity and located opposite to the front wall; and a main body defining an upper surface and a lateral surface of the cavity and joined with the front wall and the rear wall. A lower end surface of each of the front wall, the rear wall, and the main body defines a bonding surface of the cap, and the main body includes a plurality of portions layered between the rear wall and the front wall.

### CROSS-REFERENCE TO RELATED APPLICATIONS

This application is based upon and claims the benefit of priority from Japanese Patent Application No. 2022-154536, filed on Sep. 28, 2022, the entire contents of which are incorporated herein by reference.

### BACKGROUND

The present disclosure relates to a manufacturing method of a cap and a light source device, a cap, and a light source device. The use of a light source device including a laser diode as a light-emitting element is expanding to various fields. For example, a display device (near-eye display) such as a head-mounted display (HMD) including a display unit at a position close to the eyes of a user is being developed. Japanese Patent Publication No. 2020-520115 discloses a glass cover surrounding an optoelectronic component such as a laser diode, and a manufacturing method of the same.

### SUMMARY

In an exemplary embodiment, a manufacturing method of a cap according to the present disclosure is a manufacturing method of a cap having a cavity for accommodating a light-emitting element and includes providing a first plate for a front wall defining a front surface of the cavity, the front wall being made of a material that transmits light emitted from the light-emitting element; providing a second plate for a rear wall defining a rear surface of the cavity, the rear wall being located opposite to the front wall; providing a third plate for a main body defining an upper surface and a lateral surface of the cavity and joined with the front wall and the rear wall, the third plate having a plurality of through holes two dimensionally arranged along a first direction and a second direction, the first direction being included in a plane orthogonal to a thickness direction, the second direction being included in the plane and orthogonal to the first direction; producing a layered body including the third plate sandwiched by the first plate and the second plate by bonding the first plate and the third plate to each other and bonding the second plate and the third plate to each other; and singulating the layered body to obtain a plurality of caps by cutting the layered body along the first direction and the second direction. The third plate includes a plurality of sheets layered in the thickness direction, and each of the plurality of sheets has a plurality of openings defining the plurality of respective through holes at positions of the plurality of the corresponding through holes, and the plurality of openings define the plurality of through holes of the third plate by the plurality of sheets being layered.

In an exemplary embodiment, a manufacturing method of a light source device according to the present disclosure includes providing a light-emitting element and a substrate directly or indirectly supporting the light-emitting element; and bonding a cap manufactured by the manufacturing method of a cap to the substrate in such a manner that the cap covers the light-emitting element.

In an exemplary embodiment, a cap according to the present disclosure is a cap having a cavity for accommodating a light-emitting element and includes a front wall defining a front surface of the cavity, the front wall being made of a material that transmits light emitted from the light-emitting element; a rear wall defining a rear surface of the cavity, the rear wall being located opposite to the front wall; and a main body defining an upper surface and a lateral surface of the cavity, the main body being joined with the front wall and the rear wall. A lower end surface of each of the front wall, the rear wall, and the main body defines a bonding surface of the cap, and the main body includes a plurality of portions layered between the rear wall and the front wall. In an exemplary embodiment, a light source device according to the present disclosure includes a light-emitting element; a substrate directly or indirectly supporting the light-emitting element; and the cap. A bonding surface of the cap is bonded to the substrate, and the cap covers the light-emitting element.

According to certain embodiments of the present disclosure, a novel and useful cap and a manufacturing method thereof, and a light source device and a manufacturing method thereof are provided.

### BRIEF DESCRIPTION OF THE DRAWINGS

FIG. 1A is a perspective view schematically illustrating a configuration example of a light source device according to a first embodiment of the present disclosure.

FIG. 1B is a perspective view schematically illustrating a configuration example of a light source device in the middle of a manufacturing step according to the first embodiment.

FIG. 2 is an exploded perspective view of a cap according to the first embodiment.

FIG. 3 is a perspective view schematically illustrating another example of a light source device according to the first embodiment.

FIG. 4A is a cross-sectional view parallel to the YZ plane of a light source device according to the first embodiment.

FIG. 4B is a cross-sectional view parallel to the XY plane of a light source device according to the first embodiment.

FIG. 5 is an exploded perspective view illustrating an example of a panel including main bodies of six caps prior to singulation.

FIG. 6 is a perspective view of a structure including main bodies of three caps obtained by cutting the panel of FIG. 5.

FIG. 7 is an exploded perspective view of a cap according to a modification of the first embodiment.

FIG. 8A is a cross-sectional view parallel to the YZ plane of a light source device according to another modification of the first embodiment.

FIG. 8B is a cross-sectional view parallel to the XY plane of a light source device according to another modification of the first embodiment.

FIG. 9A is a cross-sectional view parallel to the YZ plane of a light source device according to a second embodiment of the present disclosure.

FIG. 9B is a cross-sectional view parallel to the XY plane of a light source device according to the second embodiment.

FIG. 9C is an enlarged view schematically illustrating a cross section of a first portion and a second portion included in a main body of a cap according to the second embodiment.

FIG. 9D is a perspective view schematically illustrating a shape of an inner wall of a main body of a cap according to the second embodiment.

FIG. 10A is a cross-sectional view parallel to the YZ plane of a light source device according to a modification of the second embodiment.

FIG. 10B is a cross-sectional view parallel to the XY plane of a light source device according to a modification of the second embodiment.

FIG. 11 is a view schematically illustrating an upper surface (left side) and a cross section (right side) taken along line A-A of a third plate.

FIG. 12 is a view schematically illustrating an upper surface (left side) and a cross section (right side) taken along line A-A of a first sheet included in the third plate.

FIG. 13 is an enlarged perspective view schematically illustrating a part of the first sheet.

FIG. 14 is a perspective view schematically illustrating a part of a state in which a plurality of sheets having tapered openings are layered.

FIG. 15 is a view schematically illustrating an upper surface (left side) and a cross section (right side) taken along line A-A of a panel formed by bonding the first plate and the second plate to the third plate.

FIG. 16A is a cross-sectional view schematically illustrating a state in which the first plate on which an antireflection film is formed is bonded to the third plate.

FIG. 16B is a plan view schematically illustrating a pattern of the antireflection film.

FIG. 17 is a view schematically illustrating an upper surface (left side) and a cross section (right side) taken along line A-A of a panel for explaining an example of how to cut the panel.

FIG. 18 is a plan view schematically illustrating an example of a position of a cutting groove used for singulation with respect to the entire panel.

FIG. 19 is a view schematically illustrating an upper surface (left side) and a cross section (right side) taken along line A-A of a panel for explaining another example of how to cut the panel.

FIG. 20 is a plan view schematically illustrating another example of a position of a cutting groove used for singulation with respect to the entire panel.

FIG. 21 is a cross-sectional view illustrating a variation of a cap.

### DETAILED DESCRIPTION

### First Embodiment

### Configuration of Light Source Device

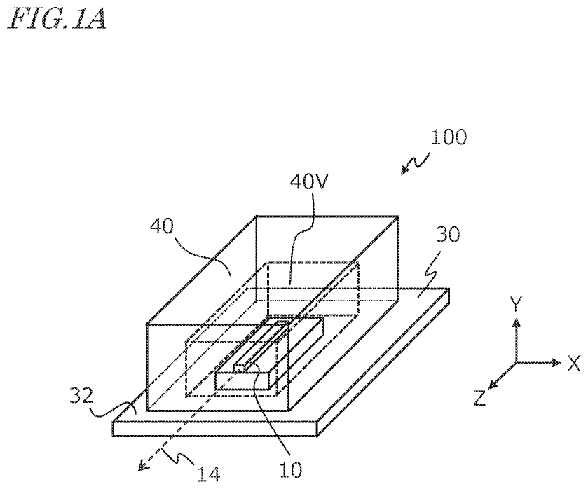

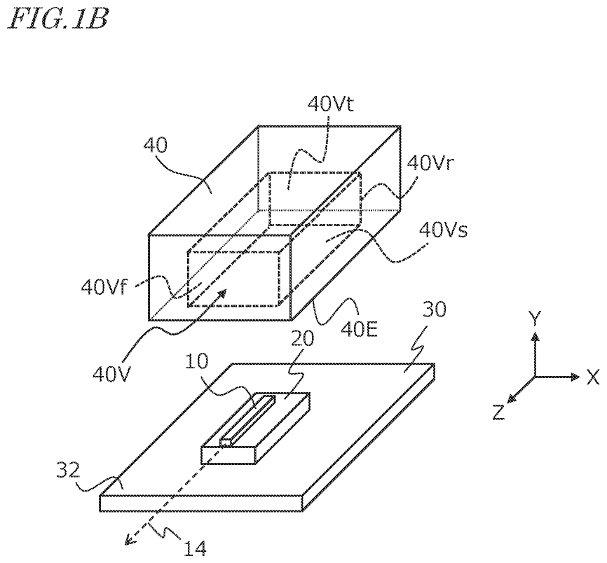

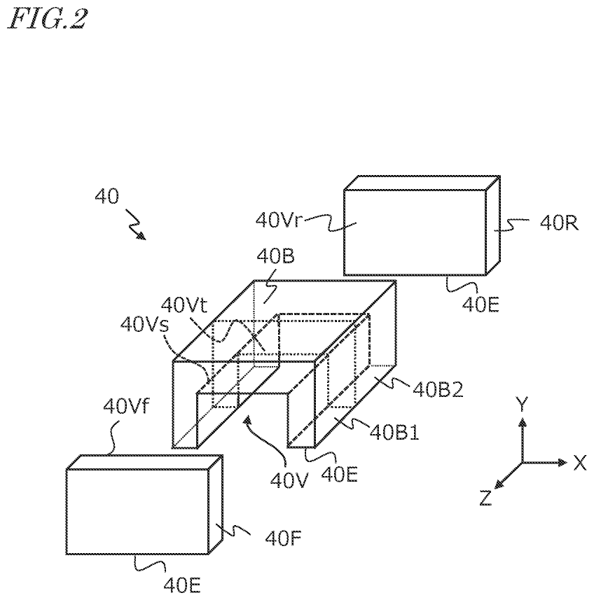

First, a schematic configuration of a light source device according to a first embodiment of the present disclosure will be described with reference to FIGS. 1A, 1B, and 2. FIG. 1A is a perspective view schematically illustrating a configuration example of a light source device 100 according to the present embodiment. FIG. 1B is a perspective view schematically illustrating a configuration example of the light source device 100 in the middle of the manufacturing step. FIG. 2 is an exploded perspective view of a cap 40 included in the light source device 100. In the accompanying drawings, an X-axis, a Y-axis, and a Z-axis orthogonal to each other are shown for reference.

The light source device 100 illustrated in the drawings includes a light-emitting element 10, a substrate 30 that directly or indirectly supports the light-emitting element 10, and the cap 40 that is fixed to the substrate 30 and covers the light-emitting element 10. Hereinafter, a case in which a laser diode is employed as the light-emitting element 10 will be described. However, a light-emitting diode (LED) or the like may be employed as the light-emitting element.

The cap 40 has a cavity 40V for accommodating the laser diode 10. As illustrated in FIG. 1B, the cavity 40V is exposed downward in a state before being fixed to the substrate 30 and has a front surface 40Vf, a rear surface 40Vr, an upper surface 40Vt, and lateral surfaces 40Vs. The cap may be referred to as a “lid.” As illustrated in FIG. 2, the cap 40 according to the present embodiment includes a front wall 40F defining the front surface 40Vf of the cavity 40V, a rear wall 40R defining the rear surface 40Vr of the cavity 40V, and a main body 40B defining the upper surface 40Vt and the lateral surfaces 40Vs of the cavity 40V. The front wall 40F is made of a material that transmits light (laser light) emitted from the laser diode 10. The rear wall 40R is located opposite to the front wall 40F across the cavity 40V. The main body 40B is joined with the front wall 40F and the rear wall 40R. As illustrated in FIG. 2, the main body 40B includes a plurality of portions including a first portion 40B1 and a second portion 40B2 arranged in the Z-axis direction. The first portion 40B1 and the second portion 40B2 according to this example have the same shape and size. In other words, each of the first portion 40B1 and the second portion 40B2 schematically has a shape and a size obtained by cutting the center of the main body 40B along a plane parallel to the XY plane. In the example of FIG. 2, the first portion 40B1 and the second portion 40B2 of the main body 40B are layered in the Z-axis direction, but the number of layered portions of the main body 40B is not limited to two. As will be described below, the size of the main body 40B in the Z-axis direction can be increased by increasing the number of layered portions (the number of layers or the number of stages). This makes it possible to increase the size of the cavity 40V in the Z-axis direction. When the size of the cavity 40V in the Z-axis direction is increased, the laser diode 10 having a large size in the Z-axis direction and a long resonator length can be accommodated in the cavity 40V.

Lower end surfaces 40E of the front wall 40F, the rear wall 40R, and the main body 40B form a lower end surface 40E of the cap 40 as a whole and define a bonding surface with respect to the substrate 30. The lower end surface 40E of the cap 40 surrounds an open surface of the cavity 40V. The lower end surface 40E of the cap 40 is bonded to a main surface 32 of the substrate 30 via a bonding material and makes it possible to hermetically seal the cavity 40V from the outside of the cap 40. It is preferable that the respective lower end surfaces 40E of the front wall 40F, the rear wall 40R, and the main body 40B are substantially coplanar. As will be described below, the lower end surface 40E of each of the front wall 40F, the rear wall 40R, and the main body 40B is formed by a cutting step using a dicing blade or the like and thus can have fine (for example, 50 μm or less) irregularities or steps. If the sizes of such irregularities or steps are smaller than the thickness of the bonding material provided between the lower end surface 40E and the main surface 32 of the substrate 30, there is no problem in bonding.

The cap 40 includes an antireflection film provided on a surface (inner surface, in other words, rear surface) of the front wall 40F facing the laser diode 10. An antireflection film can also be formed on the outer (front) surface of the front wall 40F. In the present embodiment, the inner and outer surfaces of the front wall 40F are smooth.

In the example illustrated in the drawings, the shape of the cavity 40V is schematically a rectangular parallelepiped. The shape of the cavity 40V is not limited to the rectangular parallelepiped. Details of a configuration and a production method of the cap 40 will be described below.

As the laser diode 10, for example, a laser diode that emits blue light, a laser diode that emits green light, a laser diode that emits red light, or the like can be adopted. In addition, a laser diode that emits light other than these may be adopted.

In the present description, the blue light is light having an emission peak wavelength within a range from 420 nm to 494 nm. The green light is light having an emission peak wavelength within a range from 495 nm to 570 nm. The red light is light having an emission peak wavelength within a range from 605 nm to 750 nm.

An example of a laser diode that emits blue light or a laser diode that emits green light includes a laser diode including a nitride semiconductor. For example, GaN, InGaN, and AlGaN can be used as the nitride semiconductor. An example of a laser diode that emits red light includes a laser diode including an InAlGaP-based semiconductor, a GaInP-based semiconductor, a GaAs-based semiconductor, and an AlGaAs-based semiconductor.

Laser light 14 emitted from the laser diode 10 has divergence and forms an elliptical far field pattern (hereinafter referred to as “FFP”) on a plane parallel to the emission end surface of the laser light 14. The FFP is defined by the light intensity distribution of the laser light 14 at a position away from the emission end surface. In this light intensity distribution, a portion having an intensity of 1/e² or more with respect to the peak intensity value may be referred to as a beam cross section.

In the present embodiment, the laser diode 10 is an end surface emission type having an end surface from which the laser light 14 is emitted but may be a surface emission type (VCSEL). For the sake of simplicity, the central axis of the laser light 14 is indicated by a broken line in the drawings. As described above, the actual laser light 14 spreads and diverges after being emitted from the end surface of the laser diode 10. Thus, the laser light 14 can be collimated or focused by an optical system including a lens. Such an optical system is typically provided outside the light source device 100. At least a part of the optical system including a lens for collimating or focusing may be provided in the cap 40 itself or may be arranged in the cavity 40V of the cap 40.

The central axis of the laser light 14 extends in a direction (Z-axis direction) along the main surface 32 of the substrate 30. The laser light 14 exited from the light source device 100 may be reflected by a mirror arranged outside the light source device 100, for example, in a direction perpendicular to the main surface 32 of the substrate 30.

In the illustrated example, the laser diode 10 is mounted on the main surface 32 of the substrate 30 in a state of being fixed to a submount 20. The laser diode 10 may be directly bonded to the main surface 32 of the substrate 30 without the submount 20. In these figures, wiring for connecting the laser diode 10 to an external circuit is omitted.

The substrate 30 can be formed of ceramic as a main material. Not limited to ceramic, the substrate 30 may be made of metal or a composite material of ceramic and metal. For example, aluminum nitride, silicon nitride, aluminum oxide, or silicon carbide can be used as the ceramic, copper, aluminum, or iron can be used as the metal, and copper-molybdenum, a copper-diamond composite material, or copper-tungsten can be used as the composite as the main material of the substrate 30.

A plurality of metal layers can be provided on each of the upper surface (main surface 32) and the lower surface of the substrate 30. The plurality of metal layers can include a wiring metal layer and a hermetic sealing metal layer. The wiring metal layer on the upper surface and the wiring metal layer on the lower surface can be electrically connected by the metal extending through the inside of the substrate 30. Another wiring metal layer that is not electrically connected to the wiring metal layer on the upper surface can be formed on the lower surface of the substrate 30. An example of the substrate 30 can be a multilayer ceramic substrate including wiring inside and/or outside thereof.

The submount 20 has a lower surface, an upper surface, and lateral surfaces and typically has a rectangular parallelepiped shape. The submount 20 can be made of, for example, silicon nitride, aluminum nitride, or silicon carbide. A metal layer for connecting the laser diode 10 to wiring on the substrate 30 can be provided on the upper surface of the submount 20.

The cap 40 is fixed to the substrate 30 in a state of covering the laser diode 10 supported by the substrate 30. In the illustrated example, the lower end surface 40E of the cap 40 is bonded to the main surface 32 of the substrate 30. Such bonding may be achieved through layers of metallic, inorganic, or organic materials. Thus, the laser diode 10 can be hermetically sealed. The light source device 100 in FIG. 1A may be referred to as a “semiconductor laser package.” Although the light source device 100 includes one laser diode 10 in the illustrated example, the present embodiment is not limited to such an example. A plurality of the laser diodes 10 may be arranged in one cavity 40V of the cap 40. The plurality of laser diodes 10 can typically be arranged in parallel to each emit the laser light 14 in the same direction.

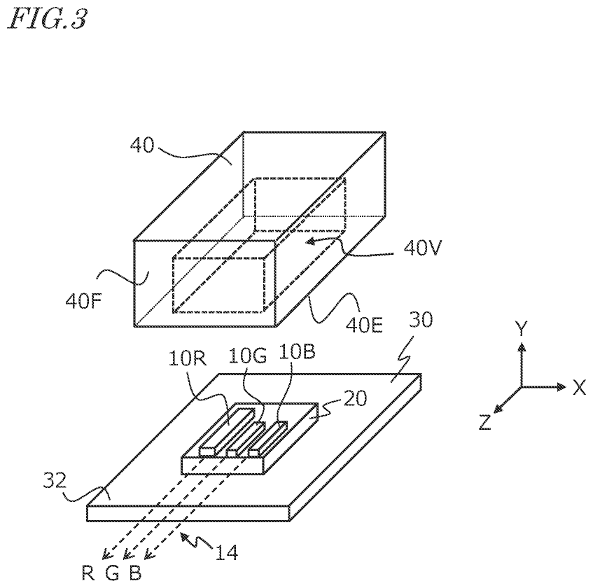

FIG. 3 is a perspective view schematically illustrating another example of a light source device according to the present embodiment. In this example, the substrate 30 includes three laser diodes 10R, 10G, and 10B arranged on one submount 20. The laser diodes 10R, 10G and 10B emit red laser light 14, green laser light 14, and blue laser light 14, respectively. These laser diodes 10R, 10G, and 10B can be accommodated in one cap 40 and hermetically sealed. The number of submounts 20 is not limited to one, and the submount 20 may be separated for each of the laser diodes 10R, 10G, and 10B.

The laser light beams 14 emitted from the laser diodes 10R, 10G, and 10B may be combined into a coaxial beam by a beam combiner or may be reflected in different directions by different micromirrors. The laser diodes 10R, 10G, and 10B may each emit the laser light 14 at different times or simultaneously. The emission of the laser light 14 is controlled by a drive circuit.

When the light source device 100 is in operation, the laser light 14 emitted from the laser diode 10 passes through the front wall 40F of the cap 40. At this time, the laser light 14 passes through the antireflection film provided on the inner surface and/or the outer surface of the front wall 40F. A portion other than the front wall 40F of the cap 40 does not need to have a light transmitting property. Furthermore, even the front wall 40F does not need to have a light transmitting property except for a portion through which the laser light 14 is transmitted. In order not to generate stray light, a light absorbing film or a light reflecting film may be formed on the surface of a portion of the cap 40 that does not need to have a light transmitting property.

### Configuration of Cap

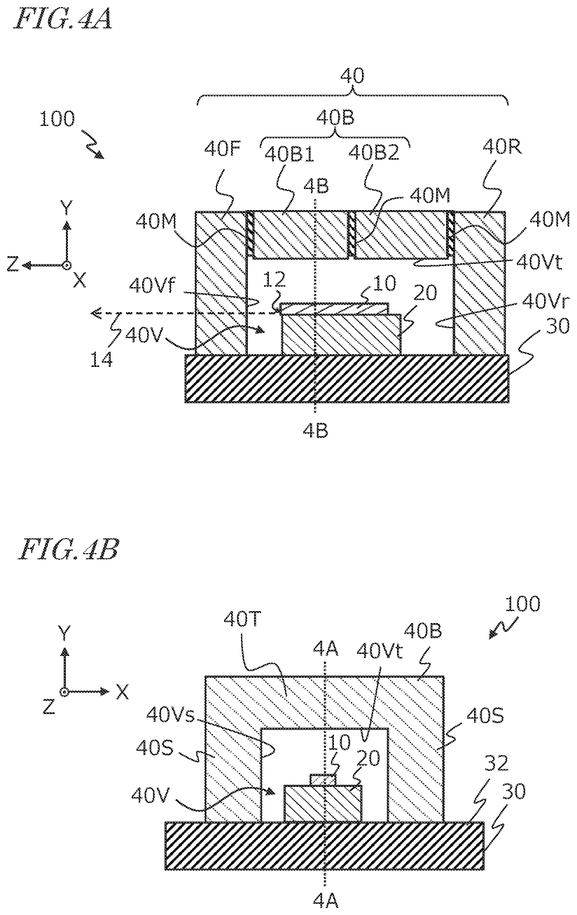

Hereinafter, a configuration example of the cap 40 according to the present embodiment will be described in detail with reference to FIGS. 4A and 4B. FIG. 4A is a cross-sectional view parallel to the YZ plane and is a view schematically illustrating a cross-section including the central axis of the laser light 14. FIG. 4B is a cross-sectional view taken along line 4B-4B in FIG. 4A and illustrating a cross section parallel to the XY plane. FIG. 4A corresponds to a cross-sectional view taken along line 4A-4A in FIG. 4B.

As illustrated in FIG. 2, the cap 40 illustrated in FIGS. 4A and 4B has a structure in which the front wall 40F and the rear wall 40R are bonded from both sides to the main body 40B located at the center. The main body 40B includes the first portion 40B1 and the second portion 40B2 layered in the Z-axis direction. As described below, the front wall 40F can be formed by a first plate such as glass, silicon, sapphire, or the like, and the rear wall 40R can be formed by a second plate such as glass, silicon, sapphire, or the like. The main body 40B can be formed by a third plate such as glass, silicon, sapphire, or the like. The third plate includes a plurality of sheets layered in a thickness direction. The plurality of portions (the first portion 40B1 and the second portion 40B2) included in the main body 40B can be formed from the plurality of sheets constituting the third plate. The rear wall 40R and the main body 40B need not be made of a material having a light transmitting property.

The front wall 40F of the cap 40 is positioned on the substrate 30 so that it intersects the laser light 14. The rear wall 40R is arranged parallel to the front wall 40F. As illustrated in FIG. 4B, the main body 40B has a U-shaped (C-shaped) cross section and joins the front wall 40F and the rear wall 40R. As illustrated in FIG. 4B, the main body 40B has a pair of lateral wall portions 40S located laterally of the laser diode 10 and a cover portion 40T located above the laser diode 10 and joining the pair of lateral wall portions 40S. Thus, the main body 40B has a shape that defines the upper surface 40Vt and the lateral surfaces 40Vs of the cavity 40V. The configuration of the cap 40 is not limited to the examples illustrated in FIGS. 4A and 4B. The main body 40B of the cap 40 may have a shape including a curved inner wall. As described above, the cavity 40V of the cap 40 may have a shape other than a rectangular parallelepiped. Other examples of the shape of the cap 40 will be described below.

In the present embodiment, the front wall 40F, the rear wall 40R, and the main body 40B are made of alkali glass. The main body 40B may be made of alkali glass, and the front wall 40F and/or the rear wall 40R may be made of alkali-free glass. The front wall 40F and/or the rear wall 40R may be made of silicon, sapphire, or the like.

“Alkali glass” refers to silicate compound glass containing ions of alkali metal elements such as Na⁺, Ka⁺, and Li⁺. Silicate compound glass having an alkali oxide concentration of 0.1 mass % or less is referred to as “alkali-free glass.” Examples of the silicate compound glass include silicate glass, borosilicate glass, and quartz glass.

As illustrated in FIG. 4A, in the present embodiment, the first portion 40B1 and the second portion 40B2 constituting the main body 40B are anodically bonded via a conductive layer 40M. The front wall 40F is anodically bonded via the conductive layer 40M formed on the surface of the main body 40B. Similarly, the rear wall 40R is anodically bonded via another conductive layer 40M formed on the surface of the main body 40B. The conductive layer 40M may have a configuration in which different kinds of metals are layered. For example, after a titanium layer is deposited on a surface as a base layer, an aluminum layer may be deposited thereon, and the conductive layer 40M may be formed from a layered body of the titanium layer and the aluminum layer. The material of the conductive layer 40M is not limited to such an example. Ni, Cr, or the like may be used as the material of the base layer.

In the present embodiment, the anodic bonding can be performed by adopting various known methods. As a result of the anodic bonding, the concentration of the alkali metal element in the front wall 40F is locally reduced in the region in contact with the conductive layer 40M. Similarly, the concentration of the alkali metal element in the rear wall 40R is also locally reduced in the region in contact with the conductive layer 40M. The conductive layer 40M may be provided on at least one of the contact surfaces of the front wall 40F, the first portion 40B1, the second portion 40B2, or the rear wall 40R. The order of bonding the front wall 40F and the rear wall 40R to the main body 40B can also be freely selected. After bonding the front wall 40F and the main body 40B, the rear wall 40R may be bonded to the main body 40B. Conversely, the front wall 40F may be bonded to the main body 40B after the rear wall 40R and the main body 40B are bonded. In addition, the front wall 40F, the first portion 40B1, the second portion 40B2, and the rear wall 40R may be bonded at the same time.

The first portion 40B1 and the second portion 40B2 of the main body 40B may be made of materials other than glass, for example, semiconductors (monocrystalline silicon, polycrystalline silicon, silicon carbide, and the like). The main body 40B does not need to have a light transmitting property. If substantially the entire cap 40 including the main body 40B is made of glass, the cap 40 may be called a “glass cap” or a “glass lid.” Although the conductive layer 40M is present only on the bonding surfaces in the example of FIG. 4A, the conductive layer 40M may be formed on the surface (inner surface) of the main body 40B on the cavity 40V side. A detailed example of a manufacturing method of the cap 40 will be described below.

According to the present embodiment, because the front wall 40F of the cap 40 is formed of a plate-shaped glass plate or glass sheet, it is easy to smooth the surfaces thereof. Furthermore, because the antireflection film can be formed on the front wall 40F before the anodic bonding, the antireflection film can be formed on the inner surface of the cap 40 with high yield even if the cap 40 is miniaturized. Similarly to the front wall 40F, an antireflection film may be formed on the rear wall 40R.

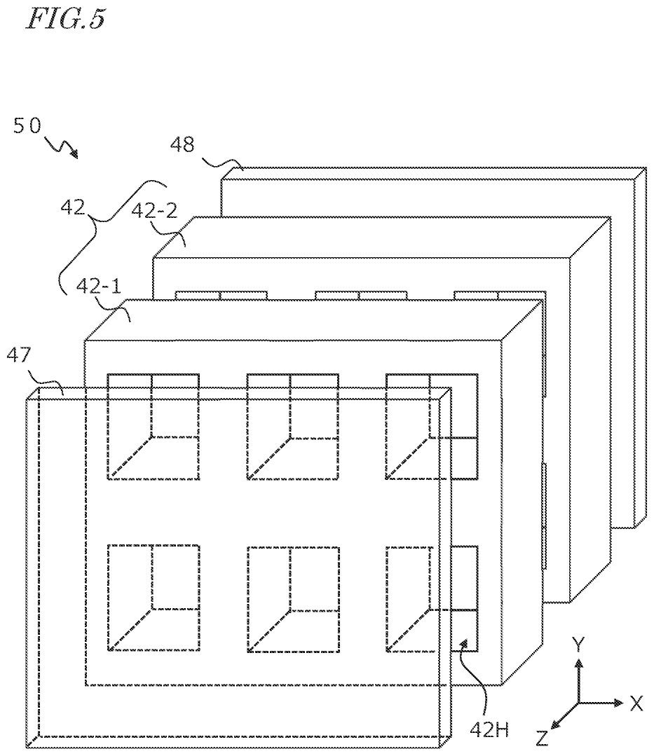

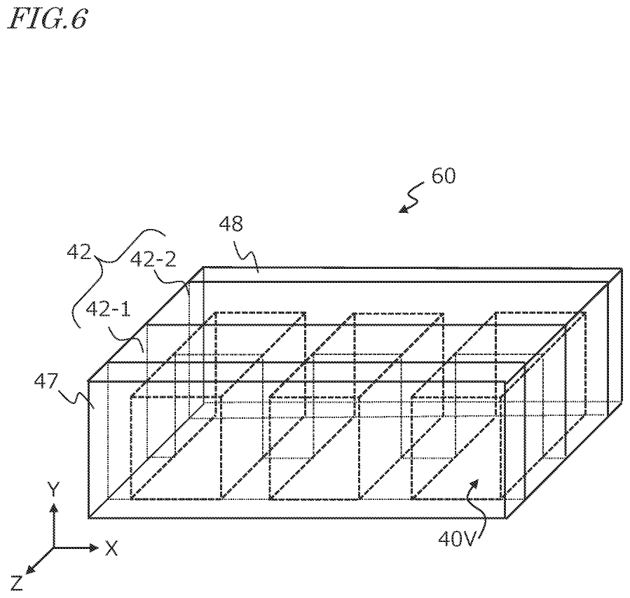

FIG. 5 is an exploded perspective view illustrating an example of a panel 50 for forming a plurality of the caps 40 (see FIG. 2) by singulation. A third plate 42 includes a first sheet 42-1 and a second sheet 42-2 that are layered. Each of the first sheet 42-1 and the second sheet 42-2 has six through holes 42H arranged in two rows and three columns. In a state where the first sheet 42-1 and the second sheet 42-2 are layered, each through hole 42H of the first sheet 42-1 and the corresponding through hole 42H of the second sheet 42-2 are continuous to form one through hole 42H. By closing the through hole 42H of the third plate 42 formed in this manner with a first plate 47 and a second plate 48 from both sides of the third plate 42, one panel (layered body) 50 can be produced. Each of the first plate 47 and the second plate 48 may be, for example, a thin glass sheet having thicknesses of about 0.2 mm to 1.0 mm. By dividing the panel 50 along the horizontal direction of FIG. 5, a structure 60 illustrated in FIG. 6 can be obtained. The structure 60 includes three main body portions which ultimately form three caps. Each of the three cavities 40V included in the structure 60 is exposed downward. By dividing the structure 60 in the vertical direction of FIG. 6, three caps can be singulated. When the caps are singulated from the panel 50, the order of cutting in the horizontal direction in the drawing and cutting in the vertical direction in the drawing can be freely selected. The vertical cut may be performed prior to the horizontal cut.

As is apparent from the above description, the size of the cavity 40V in the Z-axis direction can be increased by increasing the number of layered sheets constituting the third plate 42. The sheet constituting the third plate 42 can be, for example, about 0.2 mm to 4.0 mm thick.

Unlike the configuration illustrated in FIGS. 5 and 6, when the third plate 42 is made of a single glass sheet, it is difficult to form the cavity 40V for accommodating the laser diode 10 having a long resonator length. In this case, the thickness of the third plate 42 is to be larger than the resonator length of the laser diode 10. A deep through hole 42H is to be formed in the third plate 42 having such a large thickness. It is difficult to form a deep through hole in thick glass by drilling. However, according to the embodiment of the present disclosure, the through holes 42H are formed in the plurality of glass sheets having thicknesses smaller than the resonator length of the laser diode, and the plurality of glass sheets are layered so that the through holes 42H are aligned with each other to form the third plate 42. Therefore, it is easy to form the through holes 42.

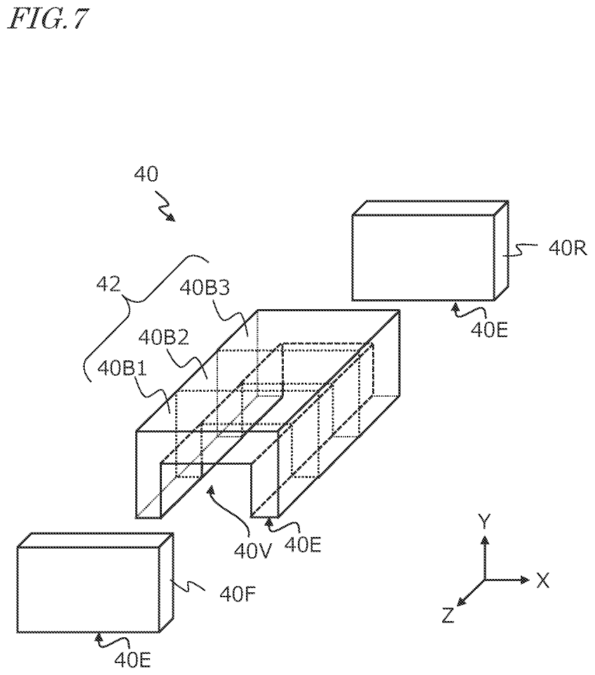

FIG. 7 is an exploded perspective view of a modification of the cap 40 according to the first embodiment. In this modification, the main body 40B includes the first portion 40B1, the second portion 40B2, and a third portion 40B3 layered in the Z-axis direction. By increasing the number of layered portions in the main body 40B, the size of the cavity 40V in the Z-axis direction is increased.

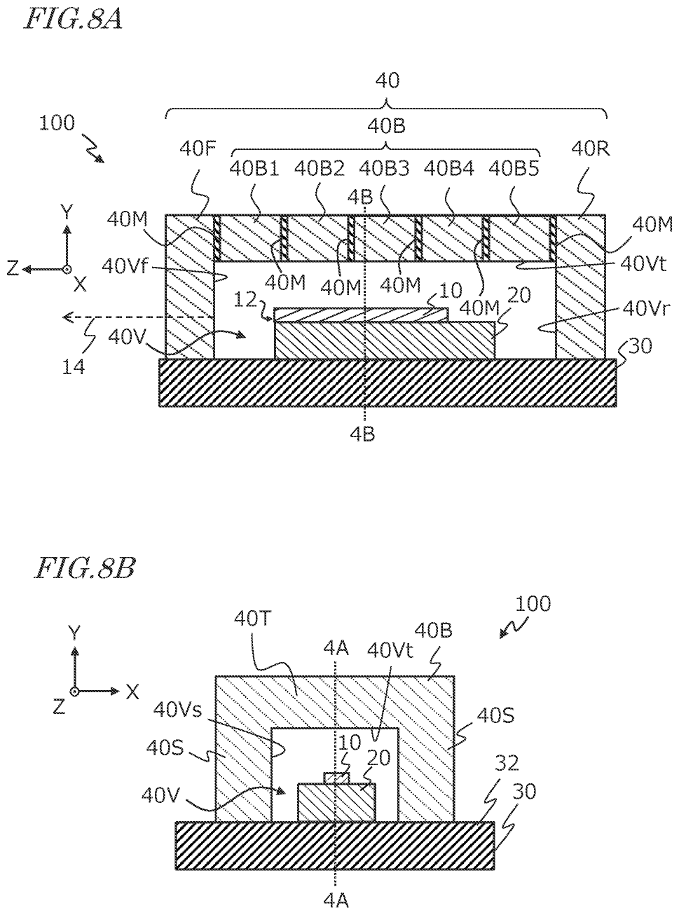

FIG. 8A is a cross-sectional view parallel to the YZ plane of the light source device 100 according to another modification of the present embodiment. FIG. 8B is a cross-sectional view parallel to the XY plane of the light source device 100 according to this modification.

The main body 40B of the cap 40 illustrated in FIG. 8A includes the first portion 40B1, the second portion 40B2, the third portion 40B3, a fourth portion 40B4, and a fifth portion 40B5 that are layered in the Z-axis direction. The conductive layers 40M are present between the first portion 40B1 and the second portion 40B2, between the second portion 40B2 and the third portion 40B3, between the third portion 40B3 and the fourth portion 40B4, and between the fourth portion 40B4 and the fifth portion 40B5, respectively. The five portions 40B1 to 40B5 are bonded to each other by anodic bonding to form one main body 40B.

### Second Embodiment

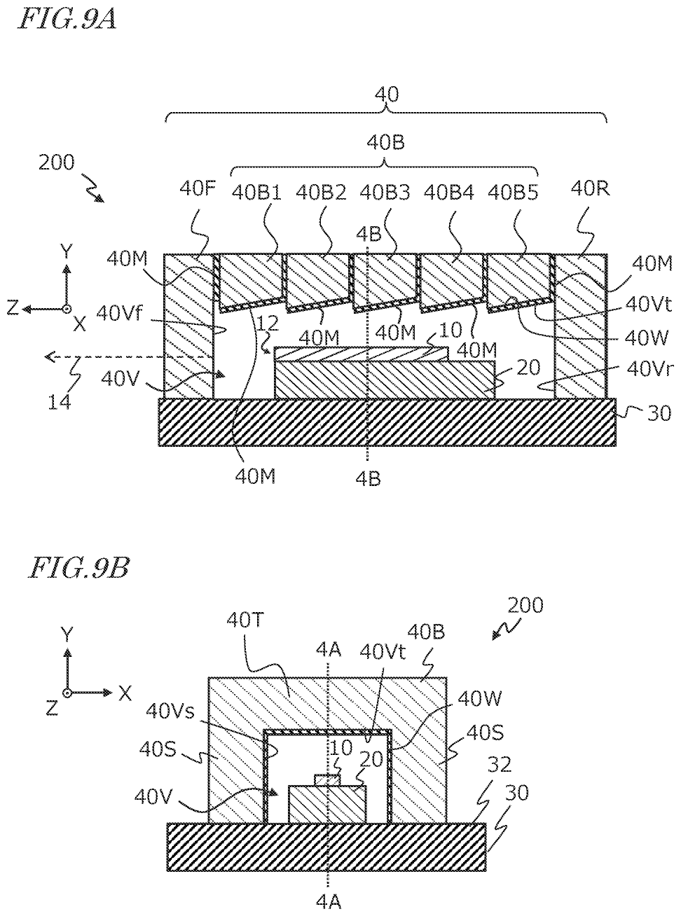

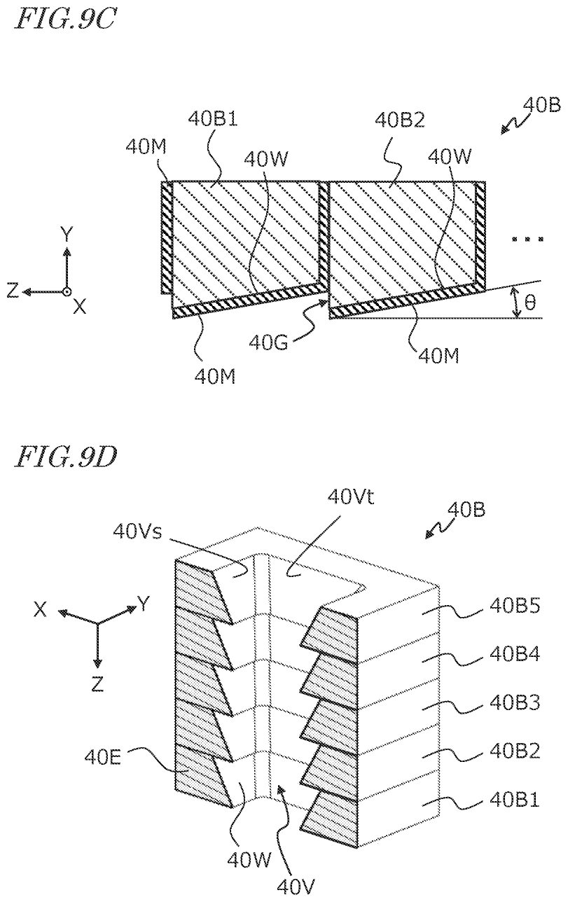

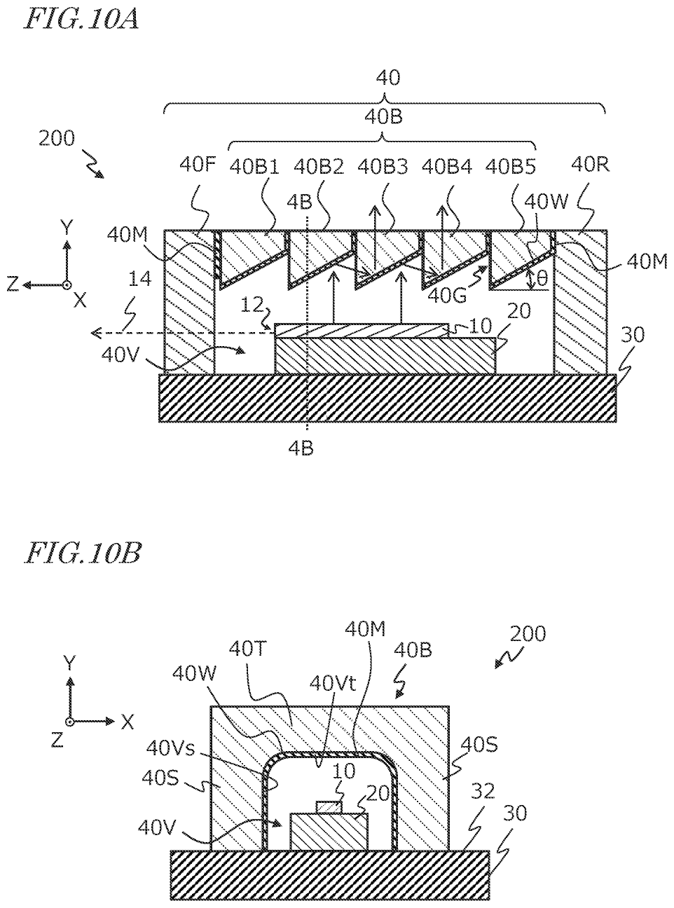

Next, a light source device 200 according to a second embodiment of the present disclosure will be described. FIG. 9A is a cross-sectional view parallel to the YZ plane of the light source device 200 according to the present embodiment. FIG. 9B is a cross-sectional view of the light source device 200 parallel to the XY plane.

Also in the present embodiment, a main body 40B of a cap 40 includes a first portion 40B1, a second portion 40B2, a third portion 40B3, a fourth portion 40B4, and a fifth portion 40B5 layered in the Z-axis direction. Each of the plurality of portions 40B1 to 40B5 has an inner wall 40W that defines an upper surface 40Vt and lateral surfaces 40Vs of the cavity 40V. The inner wall 40W has a tapered shape.

As described with reference to FIG. 8A, also in the cap 40 according to the present embodiment, conductive layers 40M are present between the first portion 40B1 and the second portion 40B2, between the second portion 40B2 and the third portion 40B3, between the third portion 40B3 and the fourth portion 40B4, and between the fourth portion 40B4 and the fifth portion 40B5, respectively. The five portions 40B1 to 40B5 are bonded to each other by anodic bonding to form one main body 40B.

In the present embodiment, the conductive layer 40M is also formed on the tapered inner wall 40W. In other words, the conductive layer 40M is also formed on the inner wall 40W of each of the plurality of portions 40B1 to 40B5 in the main body 40B. The conductive layer 40M is spaced apart from the other conductive layers 40M. When j is an integer of 1 or more and k is an integer of 2 or more (j<k), the conductive layer 40M of the j-th portion 40Bj is spaced apart from and electrically isolated from the conductive layer 40M of the k-th portion 40Bk.

FIG. 9C is an enlarged view schematically illustrating a cross section of the first portion 40B1 and the second portion 40B2 of the main body 40B. Both the inner wall 40W of the first portion 40B1 and the inner wall 40W of the second portion 40B2 are inclined at an angle θ with respect to the Z-axis direction. This angle θ is assumed to be referred to as a “taper angle.” The taper angle θ can be, for example, in a range from 5 degrees to 50 degrees. A step is present between the first portion 40B1 and the second portion 40B2, and a gap region 40G is provided between the conductive layers 40M. The conductive layer 40M is not present in the gap region 40G. Thus, when each of the portions 40B1 to 40B5 included in the main body 40B is made of translucent glass or the like, the gap region 40G functions as an electrical insulating region. Furthermore, the gap region 40G can transmit light without being shielded by the conductive layer 40M. The size of the gap region 40G (the distance between adjacent conductive layers 40M) is preferably 10 μm or more from the viewpoint of enhancing the electrical insulating property.

FIG. 9D is a perspective view schematically illustrating a shape of the inner wall 40W of the main body 40B. The inner wall 40W defines the upper surface 40Vt and the lateral surfaces 40Vs of the cavity 40V. In FIG. 9D, the conductive layer 40M is not illustrated for simplicity. In FIG. 9D, a hatched region is a lower end surface 40E of the main body 40B. A method of forming such a tapered shape will be described below.

According to the present embodiment, because the inner wall 40W of the main body 40B of the cap 40 has a tapered shape, the non-laser light (stray light) radiated from the laser diode 10 to the surroundings is reflected by the conductive layer 40M on the inner wall 40W in a direction away from the front wall 40F. When the stray light is emitted to the outside from the front wall 40F together with the laser light 14, noise is caused. Thus, it is preferable that the light other than the laser light 14 is not transmitted through the front wall 40F.

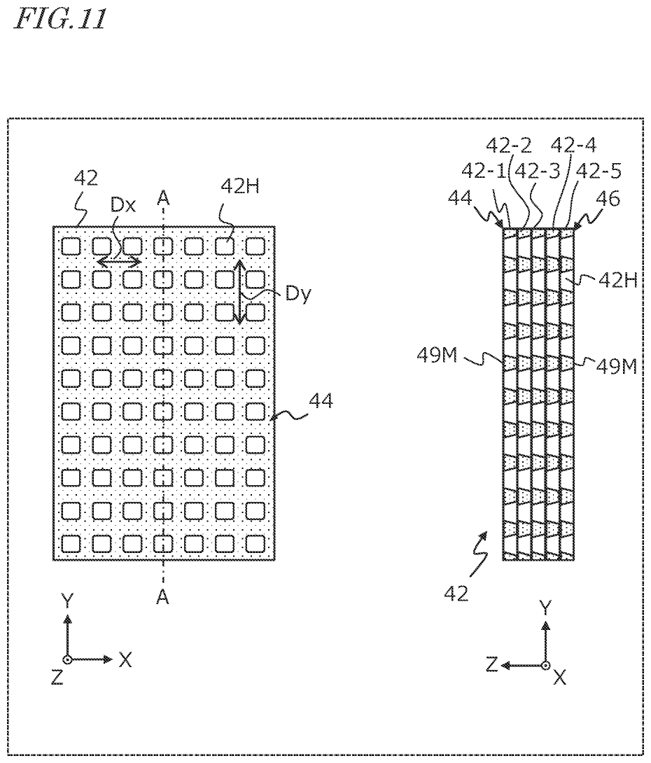

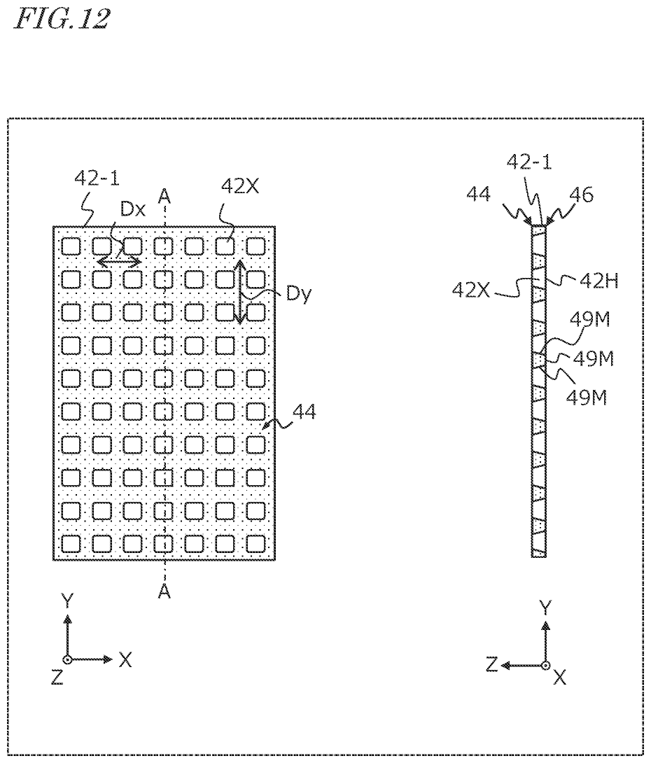

FIG. 10A is a cross-sectional view parallel to the YZ plane of the light source device 200 according to a modification of the present embodiment, and FIG. 10B is a cross-sectional view parallel to the XY plane of the light source device 200 according to this modification. In this modification, the taper angle θ is in a range from 30 degrees to 50 degrees, for example. As the taper angle θ is increased, the gap region 40G is also expanded. The main body 40B according to this modification is made of a material that transmits the peak wavelength of the laser light 14, for example, glass. Thus, the non-laser light radiated from the laser diode 10 to the surroundings is reflected by the conductive layer 40M provided on the tapered inner wall 40W, and then passes through the gap region 40G to be incident on the rear surface of the conductive layer 40M (the surface in contact with the inner wall 40W), as illustrated by the linear arrow in FIG. 10A. The non-laser light incident on the rear surface of the conductive layer 40M can be emitted from the main body 40B to the outside. Accordingly, it is possible to enhance the stray-light suppression effect for suppressing light other than the laser light 14 from being transmitted through the front wall 40F.

The gap region 40G is formed not only on the upper surface 40Vt of the cavity 40V but also on the lateral surfaces 40Vs, as illustrated in FIG. 9D, for example. Thus, the gap region 40G is present not only on the upper surface of the laser diode 10 but also at a position facing the lateral surface of the laser diode 10, and it is possible to extract non-laser light (stray light) radiated from the laser diode 10 to the surroundings from the main body 40B of the cap 40 to the outside.

A photodiode for receiving light extracted to the outside of the cap 40 may be provided on the cap 40 or at a position away from the cap 40. Such a photodiode may function as an output monitor for the laser diode 10. A light absorbing layer may be provided on at least a partial region of the surface of the cap 40. Such a light absorbing layer can absorb stray light that has passed through the gap region 40G.

The gap region 40G described above can also be provided in the cap 40 of the first embodiment as illustrated in FIG. 8A. In the example of FIG. 8A, the height of the upper surface 40Vt of the cavity 40V is substantially constant in the Z-axis direction. However, for example, by making the upper surface 40Vt of the second portion 40B2 lower than the upper surface 40Vt of the first portion 40B1, a step is formed between the first portion 40B1 and the second portion 40B2, and the gap region 40G can be provided at the position of the step.

### Manufacturing Method of Cap

Hereinafter, an embodiment of a manufacturing method of the cap 40 will be described in detail.

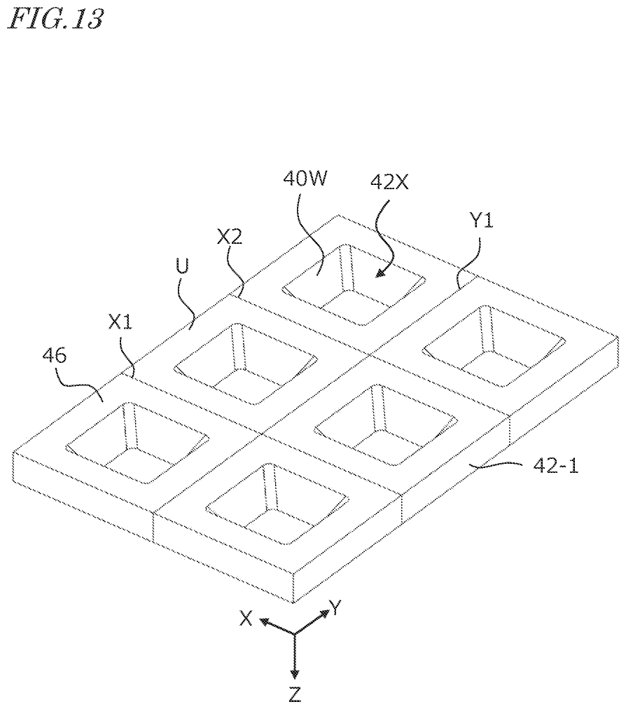

Reference is first made to FIG. 11. FIG. 11 is a view schematically illustrating an upper surface (left side) and a cross section (right side) taken along line A-A of a third plate 42. First, the third plate 42 for the main body 40B illustrated in FIG. 2 that defines the upper surface 40Vt and the lateral surfaces 40Vs of the cavity 40V and is joined with the front wall 40F and the rear wall 40R is provided.

The third plate 42 according to the present embodiment includes a plurality of sheets 42-1, 42-2, 42-3, 42-4, and 42-5 layered in the thickness direction (Z-axis direction). These sheets 42-1 to 42-5 can be made of a material that can be anodically bonded, for example glass. Each of the sheets 42-1 to 42-5 is preferably made of alkali glass. In order to carry out anodic bonding, a metal layer is arranged between sheets made of alkali glass. In addition to or instead of the metal layer, a Si layer may be arranged. The layered body in which the plurality of sheets 42-1 to 42-5 are layered can have a layered structure including, for example, a sheet 42-1 made of alkali glass, a sheet 42-2 made of alkali glass with a metal layer, a sheet 42-3 made of alkali glass with a metal layer, . . . , and a sheet 42-5 made of alkali glass with a metal layer in this order. Such a layered body can be subjected to anodic bonding in a state of being placed on a sapphire substrate having a Si layer provided on a surface thereof, for example. Hereinafter, an example of a production method of the third plate 42 having such a layered structure will be described.

The third plate 42 has a first surface (upper surface) 44 and a second surface (lower surface) 46 located opposite to the first surface 44. The third plate 42 has a plurality of through holes 42H two dimensionally arranged along a first direction (Dx direction) included in a plane (XY plane) orthogonal to the thickness direction and a second direction (Dy direction) included in the plane (XY plane) and orthogonal to the first direction (Dx direction). The through holes 42H extend from the first surface 44 to the second surface 46. In the example, the first direction Dx is parallel to the X-axis, and the second direction Dy is parallel to the Y-axis. Each through hole 42H extends along the Z-axis direction. In a plan view as seen along the Z-axis direction, the shape of each through hole 42H can be schematically a polygon such as a square or a rectangle, a circle, an ellipse, or a combination thereof In addition, a curved line may be present at a corner portion located at a vertex of the polygon.

FIG. 12 is a view schematically illustrating an upper surface (left side) and a cross section (right side) taken along line A-A of the first sheet 42-1. In this example, the other sheets 42-1 to 42-5 also have the same configuration as the first sheet 42-1. Each of the plurality of sheets 42-1 to 42-5 has a plurality of openings 42X, and each through hole 42H of the third plate 42 is defined by the plurality of openings 42X by layering the plurality of sheets 42-1 to 42-5. The step of providing the third plate 42 includes a step of providing the plurality of sheets 42-1 to 42-5 each having the plurality of openings 42X, and then forming a metal layer 49M on the lower surface of each of the plurality of sheets 42-1 to 42-5 and the inner walls of the plurality of openings 42X. According to the anodic bonding technique, the third plate 42 can be manufactured by bonding the plurality of sheets 42-1 to 42-5 to each other via the metal layer 49M. The first plate 47 and the second plate 48 may be bonded to the third plate 42 by anodic bonding after the third plate 42 is manufactured as described above, or the plurality of layered sheets 42-1 to 42-5 may be sandwiched between the first plate 47 and the second plate 48 and then all the sheets may be bonded by one anodic bonding step.

The inner walls of the plurality of openings 42X in each of the plurality of sheets 42-1 to 42-5 used in the present embodiment have a taper. FIG. 13 is an enlarged perspective view schematically illustrating a part of the first sheet 42-1. In FIG. 13, imaginary straight lines X1, X2, and Y1 that divide the six openings 42X are illustrated. In the step of singulating to be described below, the first sheet 42-1 is cut along the imaginary straight lines X1, X2, and Y1, whereby the first sheet 42-1 can be divided into parts each having a rectangular region U surrounding the opening 42X as a unit. Each rectangular region U is further divided into two portions to obtain a portion corresponding to the first portion 40B1 constituting the main body 40B of the cap 40.

The opening 42X can be formed by forming a resist layer having an opening pattern defining the shape and position of each opening 42X on the lower surface (second surface 46) of the sheet material and then removing the portion of the sheet material not masked by the resist layer, for example by sand blasting, etching or other drilling techniques. For example, by sandblasting or etching, the inner wall of the opening 42X can be tapered. The size of the tapered opening 42X decreases from the second surface 46 toward the first surface 44. After the opening 42X is formed, the resist is removed. The opening 42X can also be formed by a drilling technique such as machining or laser machining. According to such a drilling technique, it is possible not to form a taper on the opening 42X. The sizes of the opening 42X in the second surface 46 in the X direction, the Y direction, and the Z direction are, for example, 0.5 mm to 5 mm, 0.5 mm to 5 mm, and 0.2 mm to 5 mm, respectively. When the inner wall of the opening 42X is tapered, the corner of the shape of the opening 42X on the first surface 44 and the second surface 46 can be rounded. The main body 40B of the cap 40 illustrated in FIG. 10B illustrates an example of a cross-section of the cavity 40V having a shape corresponding to the shape of the opening 42X with rounded corners. As can be seen from FIG. 10B, the shape of the cross-section parallel to the XY plane of the cavity 40V need not be rectangular. In other words, a part or all of the upper surface 40Vt and the lateral surfaces 40Vs of the cavity 40V may be formed by a curved surface.

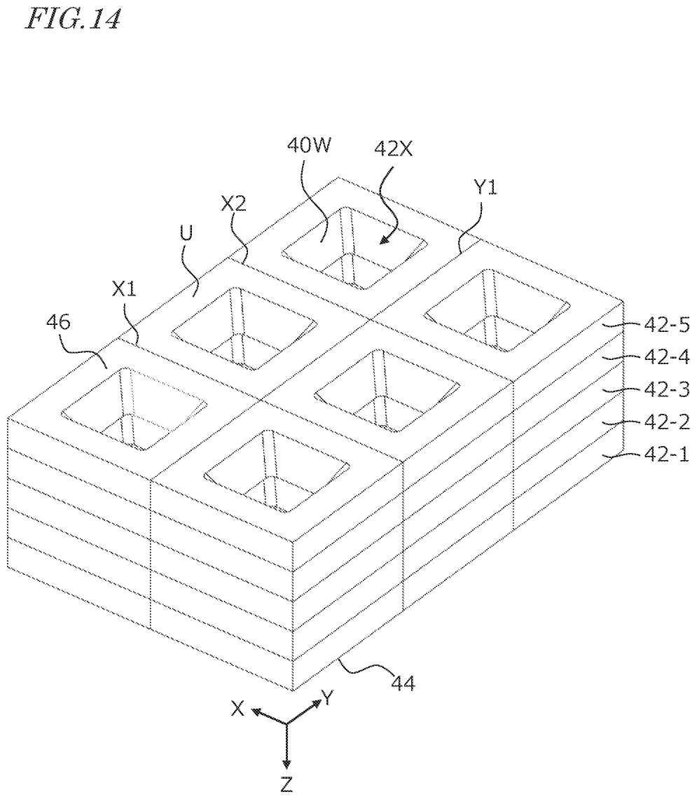

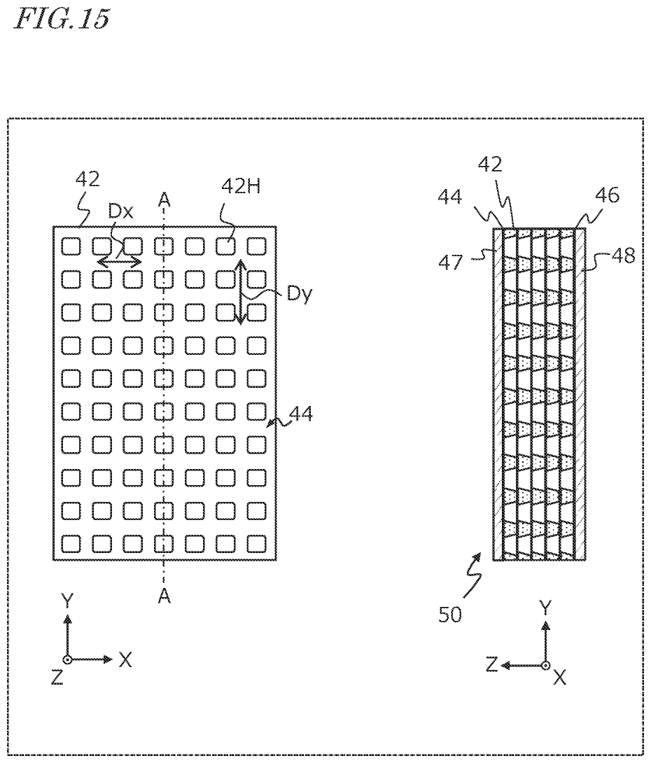

The metal layer 49M can be formed on the second surface 46 of the first sheet 42-1 in which the opening 42X having the tapered inner wall as illustrated in FIG. 13 is formed by using a thin film deposition technique such as a sputtering method. A typical example of the metal layer 49M is an aluminum layer (thickness: 50 nm to 1000 nm, for example). The metal layer 49M may be made of metals other than aluminum, for example, titanium, or may be made of a layered film of aluminum and titanium, chromium, nickel, platinum, palladium, ruthenium, or alloys containing these metals. Because the inner wall of the opening 42X is tapered, the metal layer 49M is formed not only on the second surface 46 but also on the inner wall of the opening 42X. The other sheets 42-2 to 42-5 can be manufactured in a similar manner. FIG. 14 is a perspective view schematically illustrating a part of a state in which a plurality of sheets 42-1 to 42-5 having tapered openings 42X are layered.

Because the tapered opening 42X is formed in each of the plurality of sheets 42-1 to 42-5 as described above, the metal layers for anodic bonding provided in each sheet are suppressed from coming into contact with each other. When the opening 42X does not have a tapered shape, metal layers provided on different sheets are likely to come into contact with each other to cause an electrical short circuit. Because the opening 42X is tapered, when the plurality of sheets 42-1 to 42-5 are bonded by anodic bonding, the metal layers provided on the respective sheets do not come into contact with each other, and it is possible to suppress the occurrence of an electrical short circuit.

Reference is again made to FIG. 11. As illustrated in FIG. 11, the metal layer 49M is also deposited on the first surface 44 of the third plate 42 provided with the plurality of through holes 42H.

Thereafter, as illustrated in FIG. 15, the first plate (thickness: 0.2 mm to 1.0 mm, for example) 47 is bonded to the first surface 44 of the third plate 42 on which the metal layer 49M is formed. The bonding can be performed by anodic bonding or other bonding methods, as described above. The inner face of the first plate 47 corresponds to the inner surface of the front wall 40F of the cap 40 illustrated in FIG. 1B. The first plate 47 can be made of a material that can be formed by anodic bonding, for example, glass, similarly to the second plate 48 to be described below.

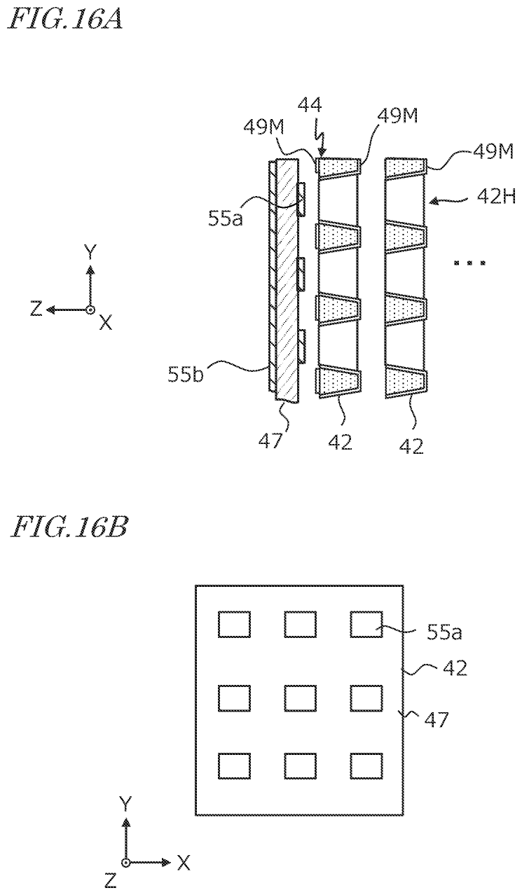

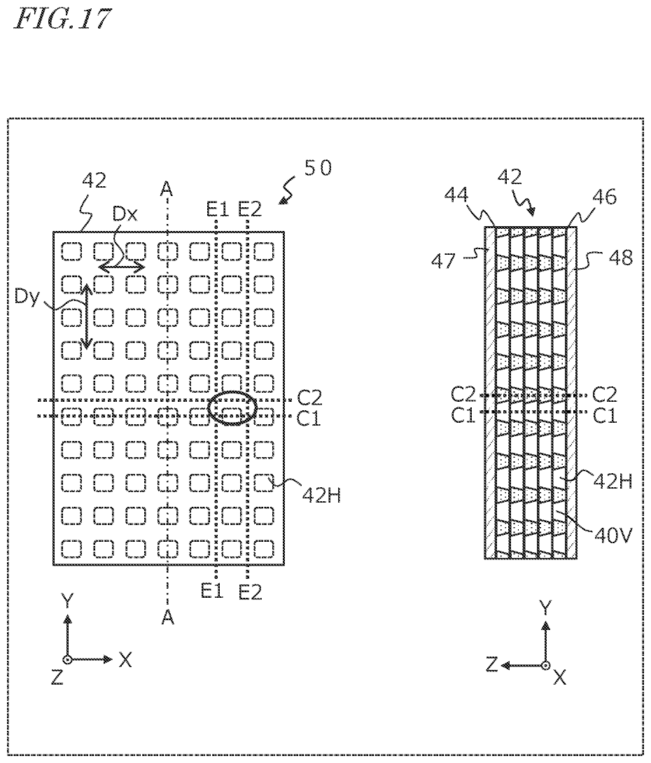

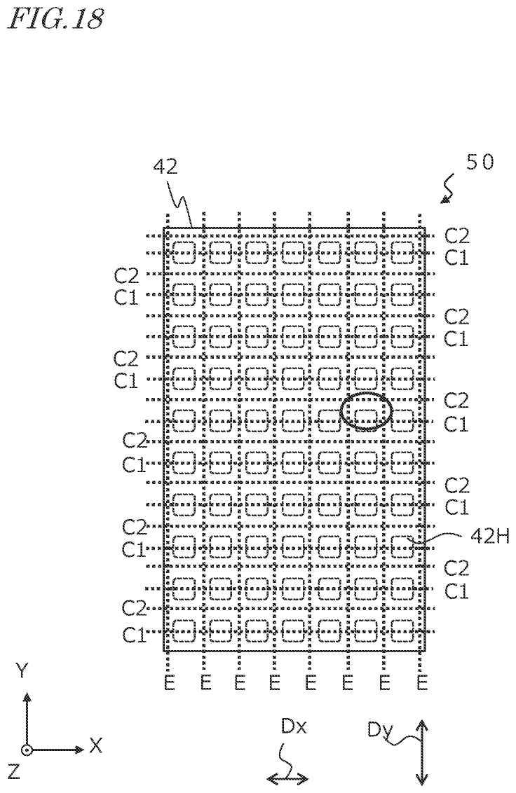

FIG. 16A is a cross-sectional view schematically illustrating a state where the first plate 47 on which antireflection films 55a and 55b are formed is bonded to the first surface 44 of the third plate 42. FIG. 16B is a plan view schematically illustrating a pattern of the antireflection film.

In the present embodiment, in order to form an antireflection film on the inner surface of the front wall 40F of the cap 40, the antireflection film 55a is formed on the rear surface of the first plate 47 (a portion that serves as the inner surface of the front wall 40F of the cap 40) before anodic bonding. In other words, the step of providing the first plate 47 includes a step of forming a plurality of the antireflection films 55a at positions corresponding to the plurality of through holes 42H of the third plate 42, respectively, on the rear surface of the first plate 47. However, the antireflection films 55a may be formed after the anodic bonding.

As can be seen from FIG. 16B, in a plan view as seen along the normal direction of the first plate 47, the periphery of each of the antireflection films 55a is located at a position shifted inward from the inner wall of the corresponding through hole 42H. In the example illustrated in the drawings, a continuous antireflection film 55b having a uniform thickness is formed on the front surface of the first plate 47 (a portion that serves as the outer surface of the front wall 40F of the cap 40). The antireflection film 55b may be formed on the front surface of the first plate 47 after all the anodic bonding is completed. A light absorbing film may be formed on the second plate 48 illustrated in FIG. 15.

Because anodic bonding is performed, on the rear surface of the first plate 47, the antireflection film 55a is not present in a region where the first plate 47 and the third plate 42 are in contact with each other, and the antireflection film 55a is formed in a region other than the region where the first plate 47 and the third plate 42 are in contact with each other. The shape and size of the antireflection film 55a are determined in consideration of the degree of misalignment when the first plate 47 on which the pattern of the antireflection film 55a is formed and the third plate 42 are bonded to each other. The antireflection film 55a covers a region of the front wall 40F on which the laser light emitted from the laser diode 10 is incident. Thus, the size of the antireflection film 55a in the X direction and the size thereof in the Y direction are preferably smaller than the size of the through hole 42H in the first surface 44 in the X direction and the size thereof in the Y direction, respectively.

In the present embodiment, as illustrated in FIG. 15, the second plate (thickness: 0.2 mm to 1.0 mm, for example) 48 is bonded to the second surface 46 of the third plate 42 on which the metal layer 49M is formed. Thus, the panel (layered body) 50 in which the through hole 42H of the third plate 42 is closed by the first plate 47 and the second plate 48 is obtained. The through hole 42H of the third plate 42 functions as the cavity 40V of the cap 40 after the step of singulating. In the following description, for the sake of convenience, a hole penetrating the third plate 42 is referred to as a “through hole” as it is, rather than a “cavity”, at a stage before singulation. In FIG. 15, the antireflection films 55a and 55b are not illustrated for simplicity.

The anodic bonding may be performed in any order. Although it is efficient to manufacture the panel 50 illustrated in FIG. 15 by anodic bonding once, the third plate 42 may be manufactured first by anodic bonding. In this case, the second plate 48 may be bonded to the third plate 42 after the first plate 47 is bonded to the third plate 42, or conversely, the first plate 47 may be bonded to the third plate 42 after the second plate 48 is bonded to the third plate 42. In a case in which the first plate 47 is bonded to the third plate 42 after the second plate 48 is bonded to the third plate 42, various processes and operations for manufacturing the panel 50 are unlikely to affect the first plate 47. Because the front wall 40F that transmits the laser light is formed by the first plate 47, it is desirable to handle the first plate 47 more carefully than the second plate 48. Thus, when the first plate 47 and the second plate 48 are not bonded to the third plate 42 at the same time, it is desirable that the first plate 47 is bonded to the third plate 42 after the second plate 48.

Thereafter, the step of singulating of cutting the panel 50 along the first direction Dx and the second direction Dy to obtain a plurality of the caps 40 from the panel 50 is performed.

Next, a basic example of a method of cutting the panel 50 for singulation will be described with reference to FIG. 17. In this example, in the step of singulating, when the panel 50 is cut along the first direction Dx, a first cutting groove (dotted line C1) crossing the center of the through holes 42H arranged along the first direction Dx is formed. When the panel 50 is cut along the second direction Dy, a second cutting groove (dotted lines E1 and E2) is formed at a position away from the through holes 42H arranged along the second direction Dy. To be more specific, another cutting groove (dotted line C2) is also formed along the first direction Dx. Accordingly, it is possible to obtain a number of the caps 40 corresponding to twice the number of the through holes 42H from the panel 50. One cap 40 is taken out from a portion surrounded by cutting grooves in a region surrounded by an ellipse in FIG. 17, for example. The cutting groove is formed by, for example, a dicing blade. In FIG. 17, the cutting grooves are schematically illustrated by the dotted lines C1, C2, E1, and E2. The cutting groove has a width, for example, in a range from 20 μm to 500 μm. In the case of cutting with a dicing blade, the width of the cutting groove is not smaller than the thickness of the blade and depends on the thickness of the blade. Each of the dotted lines C1, C2, E1, and E2 corresponds to a center line of the cutting groove having a predetermined width.

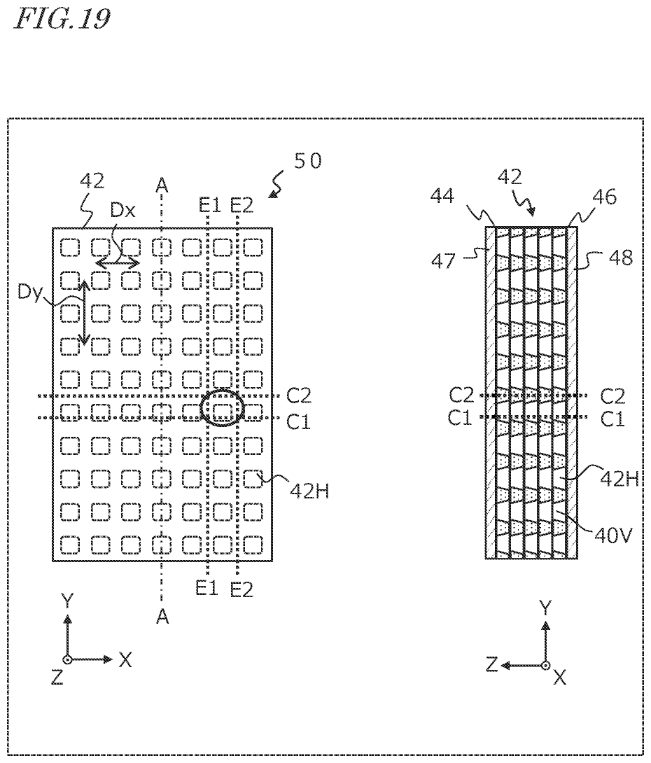

In FIG. 18, each of the dotted lines C1, C2, and E schematically represents the cutting groove used for singulation of the entire panel 50. The position of the cutting groove according to the present embodiment is not limited to the above example. For example, the dotted line C1 may pass through a position away from the center of the through hole 42H instead of passing through the center of the through hole 42H.

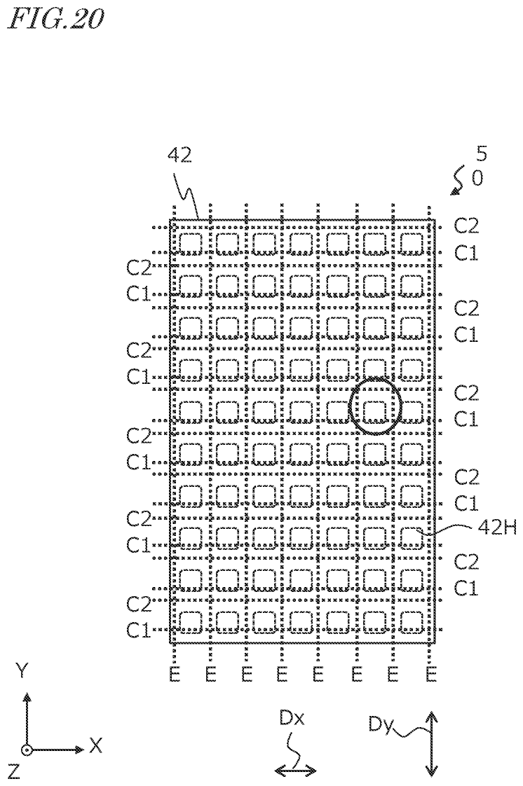

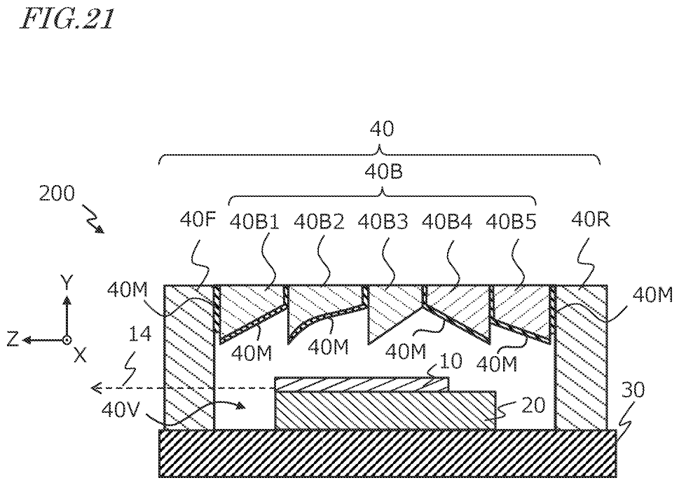

FIG. 19 is a view illustrating an example in which the cutting groove (dotted line C1) is biased toward the proximity of the inner wall of the through hole 42H rather than the center of the through hole 42H. In the step of singulating, when the panel 50 is cut along the first direction Dx, the first cutting groove (dotted line C1) is formed near the inner wall of the through hole 42H arranged along the first direction Dx extending in the first direction Dx and the thickness direction. When the panel 50 is cut along the second direction Dy, the second cutting groove (dotted lines E1 and E2) is formed at a position away from the through hole 42H arranged along the second direction Dy. To be more specific, another cutting groove (dotted line C2) is also formed along the first direction Dx. Accordingly, it is possible to obtain the cap 40 having different sizes corresponding to the number of the through holes 42H from the panel 50. One cap 40 is taken out from a portion surrounded by cutting grooves in a region surrounded by an ellipse in FIG. 19, for example. The cutting groove is formed by, for example, a dicing blade. In FIG. 20, each of the dotted lines C1, C2, and E schematically represents the cutting groove used for singulation of the entire panel 50.

The lower end surface of each cap 40 singulated in this manner is defined by the first cutting groove (dotted line C1). The lateral surface of each cap 40 is defined by the second cutting groove (dotted line E). Furthermore, the upper surface of each cap 40 is defined by another first cutting groove (dotted line C2). The surface of each cap 40 may have a rough surface caused by processing such as dicing in the step of singulating. However, because the laser light is transmitted through the smooth portion of the first plate 47, it is not adversely affected by the processed rough surface. As described above, according to the present embodiment, because the smoothness of the first plate 47 is not impaired during the manufacturing step, the portion of the cap 40 through which the laser light is transmitted can exhibit good smoothness. The surface exposed by the formation of the first cutting groove (dotted line C1) is the lower end surface of the cap 40, which is to be bonded to the substrate. Thus, smoothing processing such as polishing may be performed as necessary.

By this method, a large number of caps 40 can be made, each having the configuration illustrated in, for example, FIGS. 10A and 10B. The front wall 40F and the rear wall 40R of each cap 40 are formed by a part of the first plate 47 and a part of the second plate 48, respectively, and the main body 40B is formed by a part of the third plate 42. The conductive layer 40M is formed by a part of the metal layer 49M. By using the cap 40 manufactured in this manner, the light source device 100 illustrated in FIG. 1A or FIG. 3 can be obtained.

The arrangement pattern of the through holes 42H in the panel 50 is not limited to the arrangement pattern in the above-described example. The manner of cutting the panel 50 is also not limited to the above-described example. With respect to the method of cutting the panel 50, the entire disclosure of Japanese Patent Application No. 2021-193956 is incorporated herein by reference.

According to the present embodiment, it is possible to mass-produce the cap 40 having a height (size in the Y-axis direction) of, for example, 2 millimeters or less and a depth (size in the Z-axis direction) of, for example, 4 millimeters or more. In addition, by providing a taper on the inner wall, it is possible to suppress generation of stray light.

### Variation of Cap

FIG. 21 is a cross-sectional view illustrating a variation of the cap 40. The taper orientation, shape, size, and taper angle need not be the same in one cap 40. In the variation illustrated in FIG. 21, the conductive layer 40M is not provided in the third portion 40B3. Even when such a configuration is adopted, the stray light suppression effect can be obtained.

In addition, the inner wall of the cap 40 does not need to be constituted by a plane. When the inner wall of the opening 42X is tapered as described with reference to FIG. 13, the tapered inner wall can be formed as a curved surface like the second portion 40B2 of FIG. 21. As in the fourth portion 40B4 and the fifth portion 40B5 in FIG. 21, the angle of the taper may also change in accordance with the position in the Z-axis direction.

The cap of the present disclosure has good smoothness of the light transmitting portion, is suitable for miniaturization, and thus can be widely used as a package component of a laser diode. The light source device according to the present disclosure includes the cap that is good in smoothness of the light transmitting portion, is suitable for miniaturization, and thus can be suitably used as a small-sized light source for a head-mounted display or the like.

What is claimed is:

1. A manufacturing method of a cap having a cavity for accommodating a light-emitting element, the manufacturing method comprising:
providing a first plate for a front wall defining a front surface of the cavity, the front wall being made of a material that transmits light emitted from the light-emitting element;
providing a second plate for a rear wall defining a rear surface of the cavity, the rear wall being located opposite to the front wall;
providing a third plate for a main body defining an upper surface and a lateral surface of the cavity and joined with the front wall and the rear wall, the third plate having a plurality of through holes two dimensionally arranged along a first direction and a second direction, the first direction extending in a plane orthogonal to a thickness direction, the second direction extending in the plane and orthogonal to the first direction wherein the step of providing the third plate comprises:
providing a plurality of sheets layered in the thickness direction, each having a plurality of openings has a plurality of openings,
forming a metal layer on an upper surface of each of the plurality of sheets and an inner wall of each of the plurality of openings of the corresponding one of the plurality of sheets, and
producing the third plate by bonding the plurality of sheets to each other via the metal layer, such that the plurality of openings define the plurality of through holes of the third plate by the plurality of sheets being layered;
producing a layered body comprising the third plate sandwiched by the first plate and the second plate by bonding the first plate and the third plate to each other and bonding the second plate and the third plate to each other; and
singulating the layered body to obtain a plurality of caps by cutting the layered body along the first direction and the second direction.

2. The manufacturing method of a cap according to claim 1, wherein:
the inner wall of each of the plurality of openings in the corresponding one of the plurality of sheets has a tapered shape.

3. The manufacturing method of a cap according to claim 2, wherein:
a first metal layer formed on the inner wall of each of the plurality of openings in a corresponding first sheet of the plurality of sheets is spaced apart from a second metal layer in a second sheet of the plurality of sheets.

4. The manufacturing method of a cap according to claim 1, wherein:
in the step of singulating, a first cutting groove is formed crossing through holes of the plurality of through holes arranged along the first direction when the layered body is cut along the first direction, and a second cutting groove is formed at a position away from through holes of the plurality of through holes arranged along the second direction when the layered body is cut along the second direction.

5. The manufacturing method of a cap according to claim 4, wherein:
in the step of singulating, a position of the first cutting groove is closer to an inner wall of a through hole of the through holes arranged along the first direction than a center of the through hole, the inner wall extending in the first direction and the thickness direction.

6. The manufacturing method of a cap according to claim 1, wherein:
the first plate and the second plate are each made of glass; and
in the step of producing the layered body, the first plate and the third plate are bonded by anodic bonding, and the second plate and the third plate are bonded by anodic bonding.

7. The manufacturing method of a cap according to claim 6, wherein:
in the step of producing the layered body, the plurality of sheets of the third plate are bonded to each other by anodic bonding.

8. The manufacturing method of a cap according to claim 7, wherein:
in the step of producing the layered body, the first plate, the second plate, and the third plate are collectively bonded by anodic bonding.

9. The manufacturing method of a cap according to claim 1, wherein:
the step of providing the first plate comprises forming a plurality of antireflection films on a surface of the first plate at a position facing the plurality of the through holes of the third plate.

10. The manufacturing method of a cap according to claim 9, wherein:
in the step of singulating, the plurality of antireflection films are not cut when the layered body is cut along the first direction and when the layered body is cut along the second direction.

11. A manufacturing method of a light source device, the manufacturing method comprising:
performing the manufacturing method according to claim 1;
providing a light-emitting element, and a substrate directly or indirectly supporting the light-emitting element; and
bonding the cap to the substrate such that the cap covers the light-emitting element.

12. A cap having a cavity for accommodating a light-emitting element, the cap comprising:
a front wall defining a front surface of the cavity, the front wall being made of a material configured to transmit light emitted from the light-emitting element;
a rear wall defining a rear surface of the cavity, the rear wall being located opposite to the front wall; and
a main body defining an upper surface and a lateral surface of the cavity, the main body being joined with the front wall and the rear wall; wherein:
a lower end surface of each of the front wall, the rear wall, and the main body defines a bonding surface of the cap; and
the main body comprises a plurality of portions layered between the rear wall and the front wall, each of the plurality of portions comprising an inner wall defining the upper surface and the lateral surface of the cavity, the inner wall having a tapered shape.

13. The cap according to claim 12, wherein:
a conductive layer is located on the inner wall of each of the plurality of portions; and
the conductive layer located on the inner wall of each of the plurality of portions is spaced apart from a conductive layer formed on an inner wall of another of the plurality of portions.

14. A light source device comprising:
a light-emitting element;
a substrate directly or indirectly supporting the light-emitting element; and
a cap comprising:
a front wall defining a front surface of the cavity, the front wall being made of a material that transmits light emitted from the light-emitting element, a rear wall defining a rear surface of the cavity, the rear wall being located opposite to the front wall; and
a main body defining an upper surface and a lateral surface of the cavity, the main body being joined with the front wall and the rear wall, wherein:
a lower end surface of each of the front wall, the rear wall, and the main body defines a bonding surface of the cap, and the main body comprises a plurality of portions layered between the rear wall and the front wall, each of the plurality of portions comprising an inner wall defining the upper surface and the lateral surface of the cavity, the inner wall having a tapered shape; wherein:
a bonding surface of the cap is bonded to the substrate, and the cap covers the light-emitting element.
